(19) United States
(12) Patent Application Publication
(10) Pub. No.: US 2012/0313797 A1
(43) Pub. Date: Dec. 13, 2012

(54) ELECTRONIC DEVICE USED IN SYNCHRONOUS CONTROL SYSTEM AND SYNCHRONOUS CONTROL METHOD

(75) Inventors: HAI-SHENG LI, Shenzhen City (CN); RONG-FENG CHENG, Shenzhen City (CN); SHANG-HUI PI, Shenzhen City (CN); CHIH-SAN CHIANG, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/310,711

(22) Filed: Dec. 3, 2011

(30) Foreign Application Priority Data
Jun. 13, 2011 (CN) 201110157281.8

(51) Int. Cl. H03M 11/00

(52) U.S. Cl. 341/22

(57) ABSTRACT

An exemplary electronic device used for a synchronous control system includes an input unit, a communication unit, a storage unit, and a control module. The input unit includes at least one key including a unique key code. The storage unit stores a code table recording key codes of each of the at least one key. The control module executes the function associated with a key or a key combination manipulated by a user, and determines the key code associated with the key or the key combination. The control module further transmits the determined key codes to other electronic devices to control the other electronic devices to also execute the same instruction as the corresponding instruction associated with the determined key code associated with the key or the combination. A related method is also provided.

### BACKGROUND

1. Technical Field

The present disclosure relates to an electronic device used in a synchronous control system and a synchronous control method.

2. Description of Related Art

Usually, a synchronous control system includes a master device and a plurality of slave devices connected with the master device. The master device and the slave device are computers including key pads, touch input devices, and displays. The synchronous control system is used for learning, meetings or conferences, for example. During the meeting or a conference, the synchronous control system transmits the operation information in response to input of a user of the master device to the slave devices, and controls the slave devices to follow the master device according to the operation information. The operation information is transmitted with script, that is, the slave devices receive script transmitted from the master device. However, the slave devices cannot keep synchronous with the master device all the time because too much memory source of the slave devices is occupied for executing the script. Furthermore, the users of the slave devices cannot utilize the operation information to reproduce the process of the learning or the conference when needed after the learning or the conference is finished, which is inconvenient for users.

Therefore, what is needed is an electronic device used in a synchronous control system and a synchronous control method alleviating the limitations described above.

### BRIEF DESCRIPTION OF THE DRAWINGS

The components in the drawings are not necessarily drawn to scale, the emphasis instead being placed upon clearly illustrating the principles of an electronic device used in a synchronous control system and a synchronous control method. Moreover, in the drawings, like reference numerals designate corresponding sections throughout the several views.

FIG. 1 is a schematic diagram of a synchronous control system in accordance with an exemplary embodiment.

FIG. 2 is a block diagram of an electronic device used in the synchronous control system of FIG. 1.

FIG. 3 is a flowchart of a synchronous control method for synchronous control systems, such as the one of FIG. 1, in accordance with the exemplary embodiment.

FIG. 4 is a sub-flowchart for exchanging the modes of a master device and a slave device of the synchronous control system of FIG. 1.

FIG. 5 is a schematic view of the electronic device of FIG. 2.

### DETAILED DESCRIPTION

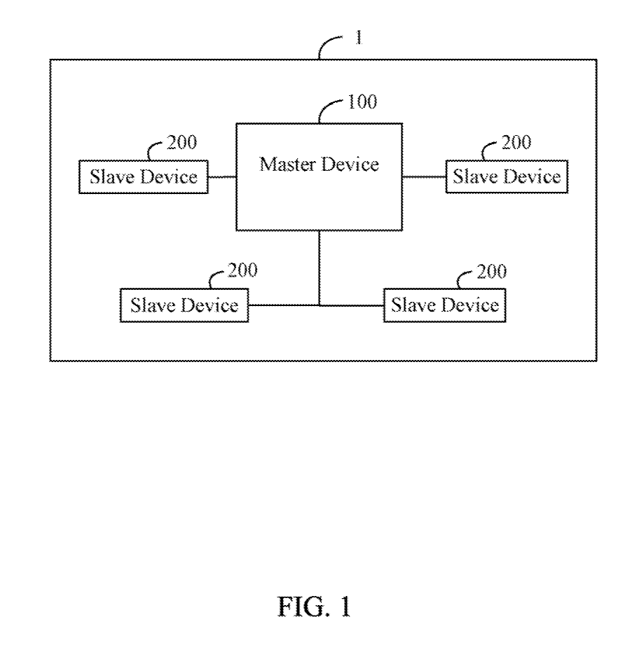

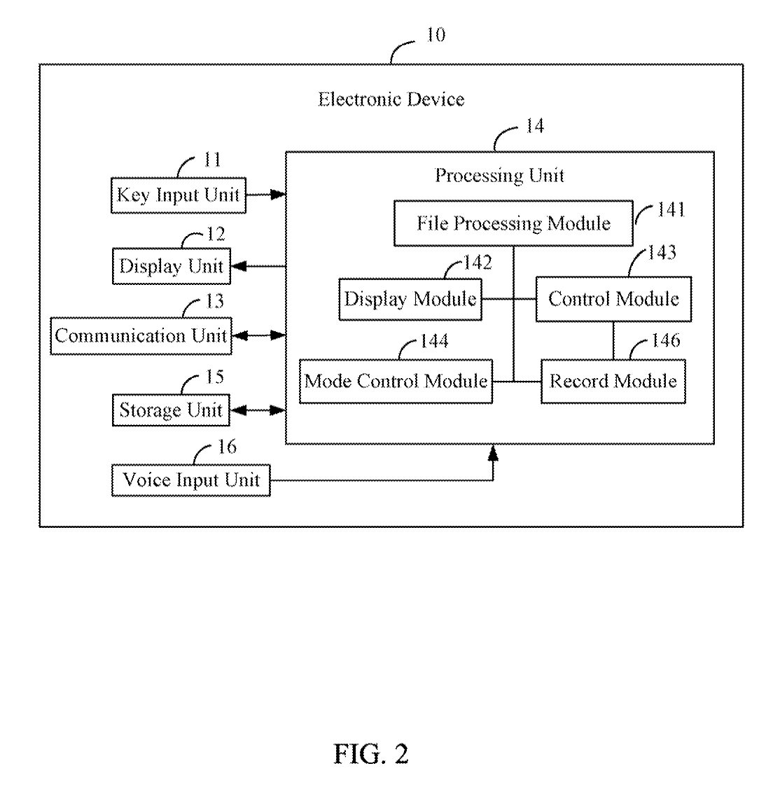

Referring to FIGS. 1 and 2, a synchronous control system 1 including a plurality of electronic devices 10 is disclosed as an exemplary embodiment. The plurality of electronic devices 10 communicate with each other according to a predetermined agreement via wires or wireless. In the embodiment, each of the electronic devices 10 provides two modes for users, that is a master mode and a slave mode. When the electronic device 10 enters a master mode, the electronic device 10 is a master device 100, and the other electronic devices 10 are slave devices 200. In the embodiment, only one electronic device 10 can be the master device 100 each time. The operation information in response to operations on the master device 100 controls the master device 100 to carry out certain functions, and the operation information is also transmitted to the slave devices 200 to control the slave devices 200 to carry out the same functions.

In this description, unless the context indicates otherwise, a reference to an “electronic device” is a reference both to a “mail device” and a “slave device”.

In the embodiment, the system 1 can be a learning system or a conference system. The electronic devices 10 have synchronous control software installed such as synchronous learning software or synchronous conference software in advance. The electronic devices 10 run the synchronous control software to enter a synchronous mode in which one of the electronic devices 10 acts as a master device 100 and the others act as slave devices 200. In the learning system, the user of the master device 100 is a teacher, and the users of the slave devices 200 are students. The electronic devices 10 are a same type of electronic device, for example, all of the electronic devices 10 are electronic readers. In an alternative embodiment, the electronic devices 10 are different types of computer devices but installed with same synchronous control software and have the same source to carry out a synchronous event.

Referring to FIG. 2, the electronic device 10 includes an input unit 11, a display unit 12, a communication unit 13, a processing unit 14 and a storage unit 15.

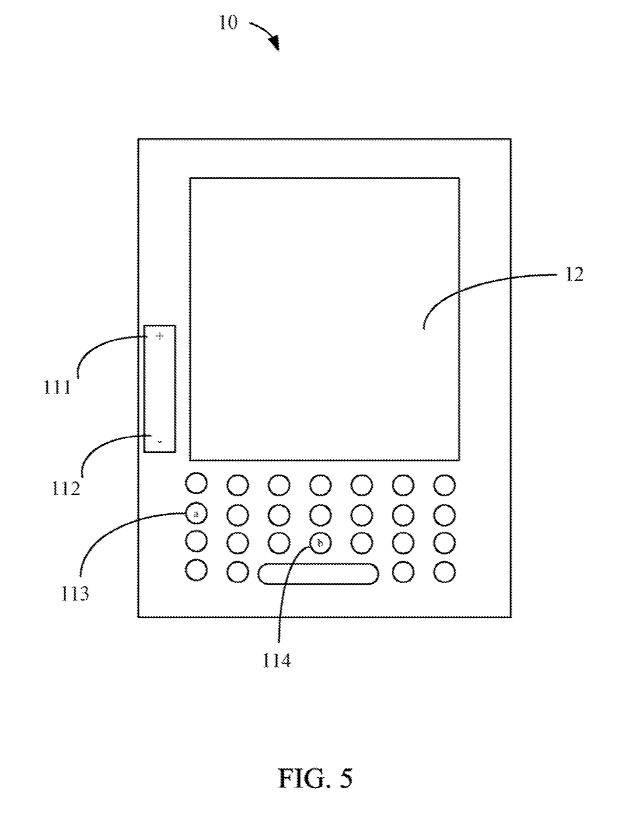

The input unit 11 is configured for generating operation signals in response to user inputs. In the embodiment, the user can choose modes for the electronic device 10, open text files, flip pages, play audio or video files via the input unit 11. The input unit 11 includes a number of mechanical keys and/or touch buttons, each of the keys is associated with a unique key code, and furthermore, each key combinations including certain keys is also associated with a unique key code. The storage unit 15 stores a code table including a plurality of key codes. Each key code is associated with a key or a key combination, and each key code is associated with a corresponding instruction. The instructions include operations on an opened file stored in the storage unit 15. In the embodiment, the key code is a six-bit binary code. For example, referring to FIG. 5, the key code of the page down key 112 is “000001”, the key code of the page up key 111 is “000010”, the key code of the key 113 labeled “a” is “000011”, the key code of the key 114 labeled “b” is “000100”, and the key code of the key combination of the key labeled “Ctrl” and the key labeled “S” is “010000”, for example. In the embodiment, the keys 112-114 can be mechanical keys or touch buttons.

The processing unit 14 includes a file processing module 141, a display module 142, a control module 143, and a mode control module 144.

The mode control module 144 is configured for controlling the electronic device 10 to enter the master mode or the slave mode in response to the choice of the user. In the embodiment, only one electronic device 10 can be the master device 100 each time.

When at least two electronic devices 10 enter the synchronous mode, and one of the electronic devices 10 enters the master mode and the other electronic devices 10 enter the slave mode, the file processing module 141 of the master device 100 opens a file in response to operations of the user via the input unit 11. The file processing module 141 of each slave device 200 opens a same file. In an alternative embodiment, when the master device 100 opens a file, the master device 100 sends a signal to all the slave devices 200. The slave devices 200 then accesses their storage unit 15 and automatically open the same file according to the signal received. For example, the signal sent to the slave devices 200 carries the name of the file opened by the master devices 100. The signal is received and is parsed by each slave device 200. The name of the file is displayed on the display unit 12 of the slave devices 200. In an embodiment, the name is for the user to click to open the file, in another embodiment, the name is to give the user a prompt so that the user can accesses the storage unit 15 to find the file and open the file. The master device 100 controls the slave devices 200 since the same file is opened.

The control module 143 of the master device 100 determines a key or a key combination depressed by the user, determines a key code associated with the depressed key or key combination according to the code table, and executes a corresponding instruction associated with the determined key code. The control module 143 further transmits the determined key code to the slave devices 200 via the communication unit 13.

The communication unit 13 of the master device 100 is configured for sending the determined key codes to the slave devices 200.

When the slave device 200 receives the key code transmitted from the master device 100, the control module 143 determines the key or the key combination associated with the key code stored in the code table. The control module 143 further executes the function associated with the key or the key combination, such as flipping page up or down, for example. The display module 142 controls the display unit 12 of the slave device 200 to display the corresponding contents of the file, which is also displayed on the display unit 12 of the master device 100.

The processing unit 14 also includes a record module 146 configured to record the key code associated with the depressed key or key combination, and the time point when the key or the key combination is depressed. The record module 146 also calculates and records the time interval between two adjacent key codes. The record module 146 further stores the key codes in a sequence of the time points, and the time interval between each two adjacent operations on an operation file A in the storage unit 15, associating with the opened file.

The communication unit 13 of the master device 100 is also configured for transmitting the time points as well as the key codes to the slave devices 200.

The record module 146 of the slave device 200 records the time points and the key codes of the depressed keys and/or key combinations transmitted/sent from the master devices 200. The record module 146 further calculates and records the time interval between two adjacent time points, and stores the key codes in a sequence of the time points, and the time interval between each two adjacent operations on the opened file in the storage unit 15.

For example, when the master device 100 displays file A, the user depresses the page down key 112 at 8:00, the record module 146 of the master device 100 records the time point—8:00 of the page down key 112 by the user. The control module 143 determines the key code “000001” of the page down key 112 stored in the code table, and transmits the key code “000001” together with the time point 8:00 to the slave devices 200. When the user depresses the key combination “Ctrl+S” at 8:10, the record module 146 of the master device 100 records the time point-8:10 of the key combination “Ctrl+S” depressed by the user. The control module 143 determines the key code “010000” associated with the key combination “Ctrl+S” stored in the code table, and transmits the key code “010000” together with the time point 8:10 to the slave devices 200. The record modules 146 of the master device 100 and the slave devices 200 record the received key code “000001” together with the time point 8:00 and key code “010000” together with the time point 8:10 in sequence. The record modules 146 also records the time interval of 10 minutes between the two consecutive key codes “000001”, “010000”. The record modules 146 further stores the recorded information as an operation file A in the storage units 15 respectively, associating with the file A.

The electronic device 10 further includes a voice input unit 16 configured for receiving voice signals of the user. The record module 146 further records the voice signals of the user of the master device 100, and stores the recorded voice signals as a voice file A in the storage unit 15, associating with the operation file A. In an embodiment, the record module 146 of the master device 100 also relays the real-time voice signals to the slave devices 200. Each slave device 200 broadcasts the voice signals, and meanwhile the record modules 146 of each slave device 200 record the voice signals relayed by the master device 100 and store the recorded voice signals as a voice file A in storage unit 15, associating with the operation file A. Therefore, the users of the slave devices 200 can receive the voice signals from the user of the master device 100, even when the slave devices 200 and the master device 100 are not in a same room. In an alternative embodiment, the record module 146 of the master device 100 does not relay the real-time voice signals to the slave device 200 but transmits the voice file A to each slave device 200 when the voice recording is finished. So the slave device 200 stores the voice file A associating with the operation file A in its storage unit 15. In still another embodiment, the voice input unit 16 of each slave device 200 is also activated during a class or an conference and records and stores voice signals as a voice file A in the storage unit 15, associating with the operation file A.

When any of the electronic devices 10 exits the synchronous mode, the electronic device 10 allows its user to reproduce the learning or conference. In detail, a button is added in the window opening the file A, if the button is activated, the electronic device 10 invokes the operation file A and the voice file A associating with the file A, and reproduces the process of the learning or conference by operating the file A using operations recorded in the operation file A and accompanying with the voice reproduced according to the voice file A synchronously.

With such a configuration, the key code of the depressed key or key combination of the master device 100 is real-timely transmitted to the slave devices 200. The slave devices 200 analyze the key code and execute the functions of the key or key combination relative to the key code. Compared to transmitting the operation information with script as the commonly used way, less memory resource of the slave devices 200 are occupied because of no need for executing the script, thus the slave devices 200 can keep synchronous with the master device 100 all the time.

In the embodiment, the input unit 11 of the slave device 200 further generates a request signal to the master device 100 for mode exchanging in response to the operation of the user of the slave device 200.

When the master device 100 receives the request signal for mode exchanging from the slave device 200, the mode control module 144 of the master device 100 controls the display unit 12 to pop up a dialog box for prompting the user to approve or refuse the request of the slave device 200. If the user approves, the mode control module 144 further generates a mode switch command for switching the master device 100 to the slave mode and the master device 100 becomes a slave device 200. Meanwhile, the mode control module 144 also transmits a signal to the slave device 200, which requests for mode exchanging, so that the slave device 200 automatically enters the master mode and become the master device 100.

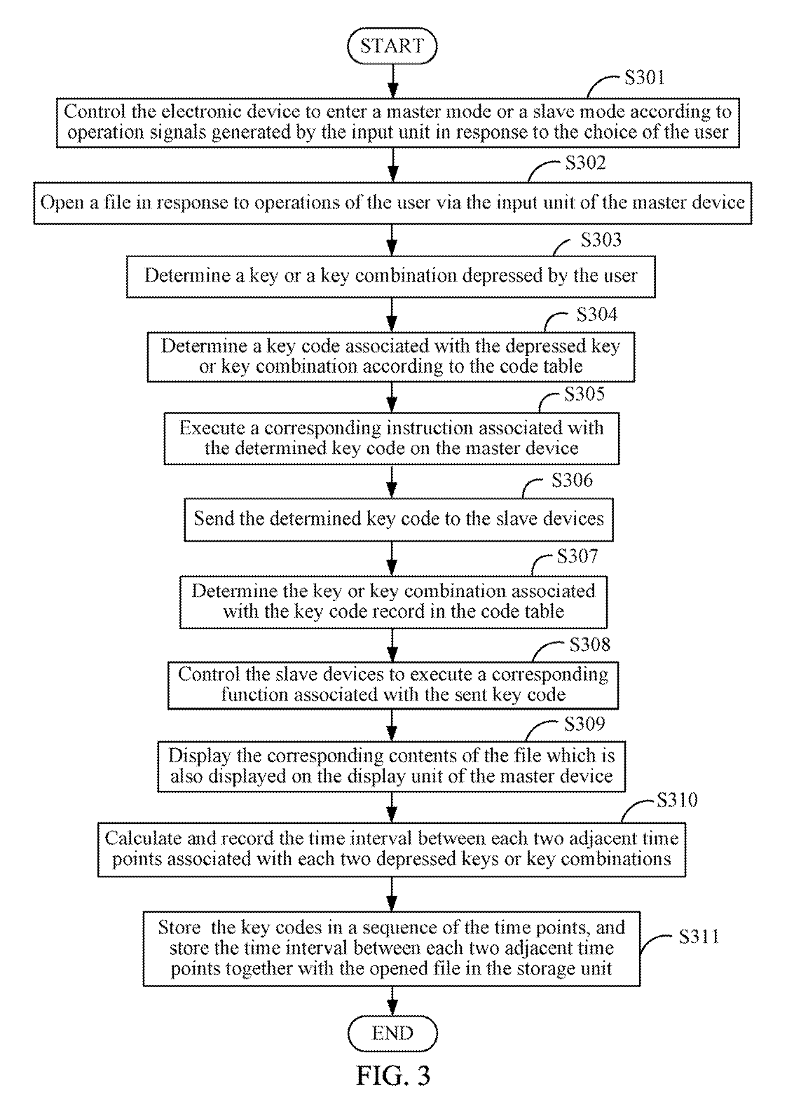

Referring to FIG. 3, a flowchart of a synchronous control method for the system 1 of FIG. 1 is shown. The method includes the following steps, each of which is tied to various components contained in the electronic device 10 of the system 1 as shown in FIG. 1.

In step S301, the mode control module 144 controls the electronic device 10 to enter a master mode or a slave mode according to operation signals generated by the input unit 11 in response to the choice of the user. In the embodiment, the electronic device 10 under the master mode is the master device 100, and the electronic device 10 under the master mode is the slave device 200.

In step S302, the file processing module 141 of the master device 100 opens a file (e.g. file A) in response to operations of the user via the input unit 11, and the file processing module 141 of each slave device 200 opens a same file (file A).

In step S303, the control module 143 of the master device 100 determines a key or a key combination depressed by the user. In an embodiment, the record module 146 of the master device 100 records the time point when the key or the key combination is input in the master device 100. In an alternative embodiment, the record module 146 of the master device 100 also calculates and records the time interval between each two adjacent time points, and/or records the voice signals of the user.

In step S304, the control module 143 of the master device 100 determines a key code associated with the depressed key or key combination according to the code table. In an embodiment, the record module 146 of the master device 100 records the codes in a sequence of the time points.

In step S305, the control module 143 of the master device 100 executes a corresponding instruction associated with the determined key code on the master device 100.

In step S306, the communication unit 13 of the master device 100 sends the determined key code to the slave devices 200. In an embodiment, the communication unit 13 of the master device 100 further transmits the time point corresponding to the key code to the slave devices 200. In an alternative embodiment, the communication unit 13 of the master device 100 also transmits the voice signals of the user to the slave devices 200.

In step S307, the control modules 143 of the slave devices 200 determine the key or key combination associated with the key code record in the code table.

In step S308, the control modules 143 of the slave devices 200 control the slave devices 200 to execute a corresponding instruction associated with the sent key code. That is, the control module 143 of the slave device 200 executes the same manipulation on the file A manipulated by the user of the master device 100.

In step S309, the display module 142 of the slave device 200 controls the display unit 12 of the slave device 200 to display the corresponding contents of the file A which is also displayed on the display unit 12 of the master device 100.

In step S310, the record module 146 of the slave device 200 calculates and records the time interval between each two adjacent time points associated with each two depressed keys or key combinations. In an alternative embodiment, the record module 146 of the slave device 200 records the key codes associated with the depressed keys or key combinations in a sequence of the time points, and records the time interval between each two adjacent time points.

In step S311, the record module 146 of the slave device 200 stores the key codes in a sequence of the time points, and stores the time interval between each two adjacent time points together with the opened file in the storage unit 15.

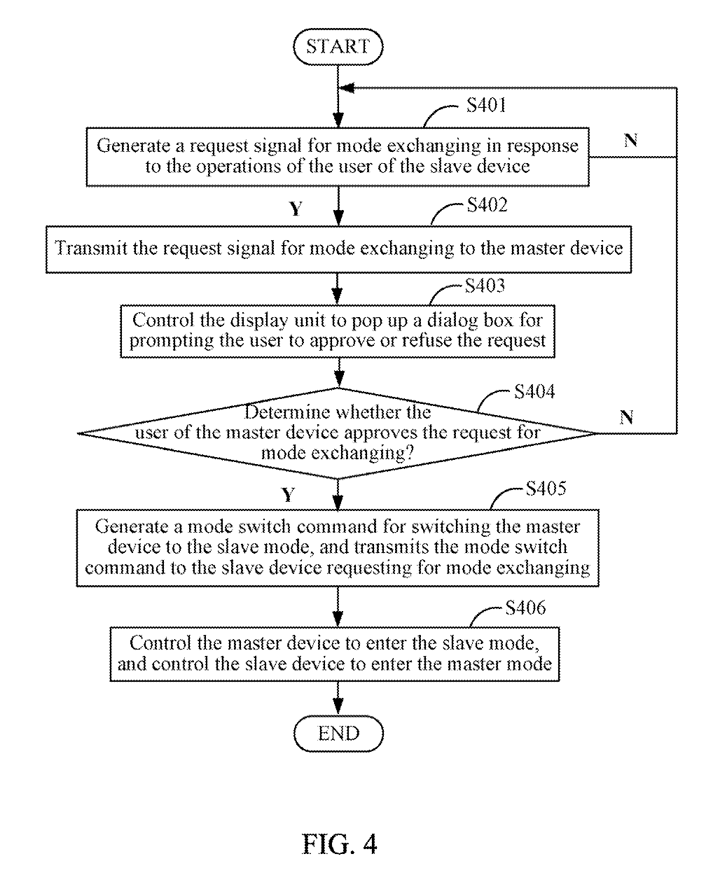

Referring to FIG. 4, a sub-flowchart for exchanging the modes of the master device 100 and the slave device 200 sent the request for mode exchanging of the synchronous control system 1 of FIG. 1 is shown. The method includes the following steps, each of which is tied to various components contained in the electronic device 10 of the system 1 as shown in FIG. 1.

In step S401, the input unit 11 of the slave device 200 generates a request signal for mode exchanging in response to the operations of the user of the slave device 200.

In step S402, the communication unit 13 of the slave device 200 transmits the request signal for mode exchanging to the master device 100.

In step S403, the mode control module 144 of the master device 100 controls the display unit 12 to pop up a dialog box for prompting the user to approve or refuse the request from the slave device 200.

In step S404, mode control module 144 of the master device 100 determines whether the user of the master device 100 approves the request for mode exchanging according to the choice of the user. If yes, the process goes to step S405, otherwise, the process goes back to step S401.

In step S405, the mode control module 144 of the master device 100 generates a mode switch command, and transmits the mode switch command to the slave device 200 requesting for mode exchanging.

In step S406, the mode control module 144 of the master device 100 controls the master device 100 to enter the slave mode, and the mode control module 144 of the slave device 200 controls the slave device 200 to enter the master mode. Thus, the master device 100 becomes a slave device 200 and the slave device 200 become the master device 100.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. An electronic device for controlling a plurality of other similar electronic devices, the electronic device comprising:
an input unit comprising a plurality of keys;
a storage unit storing a code table including a plurality of key codes, each key code associated with a key or a key combination, each key code associated with a corresponding instruction; and
a control module configured for determining a key or a key combination depressed by a user, and determining a key code associated with the depressed key or key combination according to the code table, and executing a corresponding instruction associated with the determined key code; and
a communication unit configured for sending the determined key code to other similar electronic devices to control modules thereof to execute same instructions as said corresponding instruction associated with the determined key code.

2. The electronic device as described in claim 1, further comprising a record module configured to record a time point when the key or the key combination is depressed; wherein the communication unit is further configured for transmitting the time point as well as the key code to the other similar electronic devices.

3. The electronic device as described in claim 2, wherein the record module is further configured to calculate and record the time interval between two adjacent time points.

4. The electronic device as described in claim 3, wherein the instructions include operations on an opened file stored in the storage unit, the record module is further configured to store the key codes in a sequence of the time points, and the time interval between each two adjacent operations on the opened file.

5. The electronic device as described in claim 4, wherein the electronic device is an electronic reader, the opened file is a text file displayed on the electronic reader.

6. The electronic device as described in claim 1, further comprising a mode control module configured for controlling the electronic device to enter a master mode where the electronic device is configured to control other similar electronic devices each to execute an instruction same as an instruction associated with a key or a key combination input in the electronic device in a synchronized manner, or a slave mode where the electronic device is configured to execute same instructions as an instruction associated with the key or key combination input in another similar electronic device in a synchronized manner.

7. The electronic device as described in claim 6, wherein when the electronic device is in the master mode, the mode control module is further configured to prompt the user to approve or refuse a request for operating the electronic device in the slave mode from another similar electronic device in the slave mode.

8. The electronic device as described in claim 1, wherein the control module is configured to execute an instruction associated with a key code sent from another similar electronic device.

9. A method for synchronously controlling an electronic device in a slave mode using another similar electronic device in a master mode, each of the electronic devices including a plurality of keys, and a storage unit storing a code table including a plurality of key codes, each key code associated with a key or a key combination, each key code associated with a corresponding instruction executable on each electronic device; comprising:
determining a key or a key combination input by a user in the electronic device in the master mode;
determining a key code associated with the depressed key or key combination according to the code table;
executing a corresponding instruction associated with the determined key code on the electronic device in the master mode; and
sending the determined key code from the electronic device in the master mode to the electronic device in the slave mode to control the electronic device in the slave mode to execute a corresponding instruction associated with the sent key code.

10. The method as described in claim 9, further comprising: transmitting the time point from the electronic device in the master mode to the electronic device in the slave mode.

11. The method as described in claim 9, further comprising: recording the voice signals of the user.

12. The method as described in claim 9, further comprising:
generating a request signal for mode exchanging using the electronic device in the slave mode; and
transmitting the request signal from the electronic device in the slave mode to the electronic device in the master mode;
receiving the request signal using the electronic device in the master mode;
prompting the user of the electronic device in the master mode to approve or refuse the request;
controlling the electronic device in the master mode to switch from the master mode to the slave mode if the request is approved, and
controlling the electronic device which sends the request to enter the master mode.

13. The method as described in claim 9, further comprising:
recording a time point when the key or the key combination is input in the electronic device in the master mode; and
storing the key codes in a sequence of the time points.

14. The method as described in claim 13, further comprising: calculating and recording the time interval between each two adjacent time points.
